(19) United States
(12) Patent Application Publication
(10) Pub. No.: US 2026/0136741 A1
(43) Pub. Date: May 14, 2026

(54) DISPLAY MODULE AND METHOD FOR MANUFACTURING THE SAME

(71) Applicant: Qisda Corporation, Taoyuan City (TW)

(72) Inventor: Po-Fu WU, Taoyuan City (TW)

(73) Assignee: Qisda Corporation, Taoyuan City (TW)

(21) Appl. No.: 19/359,896

(22) Filed: Oct. 16, 2025

(30) Foreign Application Priority Data
Nov. 13, 2024 (CN) 202411614386.5

(51) Int. Cl. H10H 29/80; H10H 20/821; H10H 29/01

(52) U.S. Cl. CPC H10H 29/842; H10H 20/821; H10H 29/034

(57) ABSTRACT

The present invention is related to a display module and a method for manufacturing the same. The method comprises the following steps. Provide a circuit board where a plurality of pixel units are disposed. Place a masking tool on the circuit board, wherein the masking tool include a plurality of masking elements, the masking elements respectively correspond to the pixel units, and a single one of the masking elements surrounds a single one of the pixel units. Form an opaque layer on the circuit board, wherein the opaque layer is formed in areas between the masking elements and is not in contact with the pixel units. Move the masking tool away from the circuit board.

This application claims the benefit of People’s Republic of China application Serial No. 202411614386.5, filed on November 13, 2024. The contents of this application are incorporated herein by reference.

### TECHNICAL FIELD

The present invention is related to a display module and a method for manufacturing the same, and is in particular related to a display module and a method for manufacturing the same that are appled to a dispilay system of the direct view LED.

### BACKGROUND

In the field of display systems of the direct view light emitting diode (commonly referred to as DVLED), the areas without light-emitting units on a DVLED circuit board are generally coated with ink to achieve an aesthetically pleasing appearance. However, during the ink coating process, due to the variations in the heights of the individual LEDs and the large number thereof, it is difficult to prevent the ink from covering the light-emitting surfaces of the LEDs. When only a few LEDs have their light-emitting surfaces covered by the ink, the ink can be subsequently removed from the surfaces of the LEDs by a plasma process to avoid degradation of the display performance. Nevertheless, if the process control of the ink coating is poor, resulting in an excessive number of LEDs having their surfaces covered by the ink, the corresponding DVLED circuit board can only be scrapped, which increases the manufacturing cost.

In view of the foregoing, there is a need in the art to develop an improved technique that can enhance the production yield of DVLED circuit boards and avoid an increase in manufacturing cost.

### SUMMARY

According to an aspect of the present invention, a method for manufacturing a display module is provided. The method includes the following steps. Provide a circuit board, wherein a plurality of pixel units are disposed on the circuit board. Place a masking tool on the circuit board, wherein the masking tool includes a plurality of masking elements that respectively correspond to the pixel units, and a single one of the masking elements surrounds a single one of the pixel units. Form an opaque layer on the circuit board, wherein the opaque layer is disposed in areas between the masking elements and is not in contact with the pixel units. Move the masking tool away from the circuit board.

According to another aspect of the present invention, a display module is provided. The display module comprises a circuit board, a plurality of pixel units, an opaque layer and and a protective layer. The pixel units are disposed on the circuit board. The opaque layer is formed on the circuit board and is not in contact with the pixel units. The protective layer is formed on the circuit board and is in contact with the circuit board, the pixel units and the opaque layer.

In comparison with the prior art, the display module and the method for manufacturing the same in the present invention can prevent the opaque layer from covering the pixel units, thereby eliminating the conventional step of removing black ink from the surfaces of the pixel units by plasma, and even avoiding the need for conventional scrapping. Accordingly, the display module and the method for manufacturing the same in the present invention can overcome the problems in the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a flowchart of a method for manufacturing a display module according to an embodiment of the present invention.

FIGS. 2, 3, 4A, 4B and 5 illustrate exemplary situations of implementing steps of the method for manufacturing the display module according to an embodiment of the present invention.

FIG. 6 illustrates a flowchart of a method for manufacturing a display module according to another embodiment of the present invention.

FIGS. 7A and 7B illustrate exemplary situations of implementing steps of the method for manufacturing the display module and the display module according to an embodiment of the present invention.

FIG. 8 illustrates a top view of a masking tool used in the method for manufacturing the display module according to an embodiment of the present invention.

FIG. 9 illustrates a schematic view of a masking tool used in the method for manufacturing the display module according to an embodiment of the present invention.

FIG. 10 illustrates a schematic view of a masking tool used in a method for manufacturing the display module according to another embodiment of the present invention.

### DETAILED DESCRIPTION

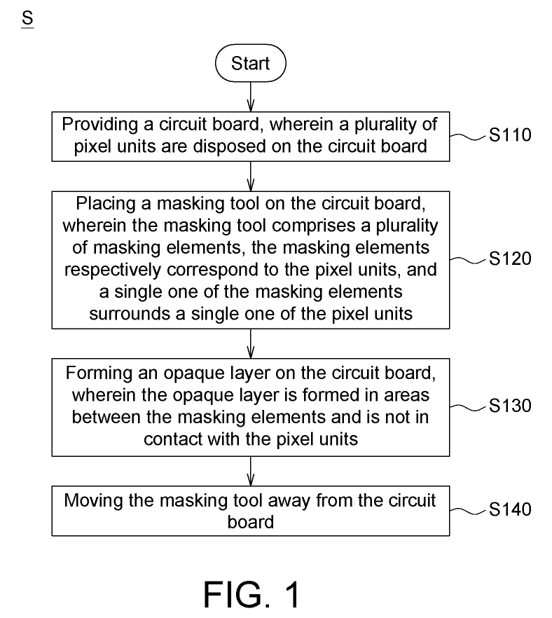

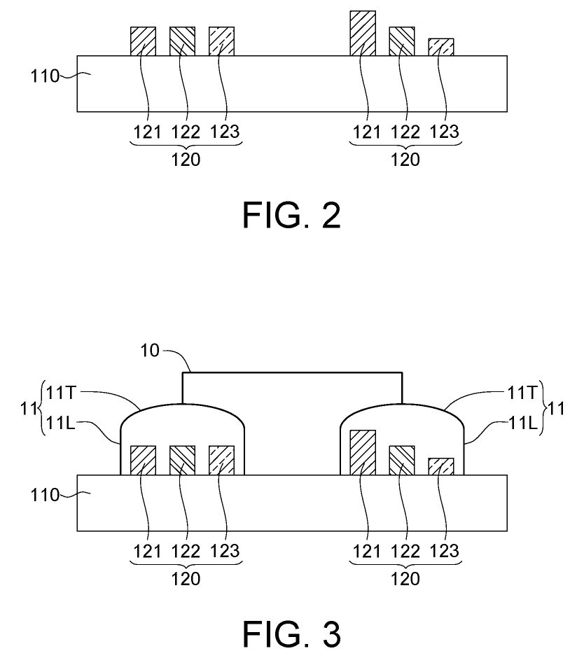

Please refer to FIGS. 1, 2, 3, 4A, 4B, and 5. FIG. 1 illustrates a flowchart of a method S for manufacturing a display module 100 according to an embodiment of the present invention. FIGS. 2, 3, 4A, 4B, and 5 illustrate situations of implementing steps of the method S for manufacturing the display module 100.

The method S for manufacturing the display module 100 according to an embodiment of the present invention may mainly comprise steps S110 to S140. The following description explains each step with reference to the contents shown in FIGS. 2, 3, 4A, 4B, and 5.

First, in the step S110, a circuit board 110 is provided. The circuit board 110, for example, may be a circuit board applied to a display system of a direct view light-emitting diode (DVLED). A plurality of pixel units 120 may be disposed on the circuit board 110. As shown in FIG. 2, in this embodiment, two pixel units 120 disposed on the circuit board 110 are taken as a representative example for illustration. The pixel unit 120 may include a plurality of sub-pixels, such as, but not limited to, three sub-pixels 121, 122, and 123. As shown in FIG. 2, the left sub-pixels 121, 122, and 123 may have the same height, while the right sub-pixels 121, 122, and 123 may have different heights from each other. For example, in this embodiment, the sub-pixels 121, 122 and 123 are a red sub-pixel, a green sub-pixel and a blue sub-pixel, respectively. However, the invention is not limited thereto. In other embodiments, the pixel unit 120 may include other different combinations of sub-pixels, such as two sub-pixels including a red sub-pixel and a blue sub-pixel, two green sub-pixels, or four sub-pixels including a red sub-pixel, a green sub-pixel, a blue sub-pixel and a white sub-pixel.

Next, in the step S120, place a masking tool 10 on the circuit board 110. The masking tool 10 may include a plurality of masking elements 11. As shown in FIG. 3, in this embodiment, the masking tool 10 includes two masking elements 11 as a representative example for illustration. The number of masking elements 11 corresponds to the number of pixel units 120. Specifically, each masking element 11 corresponds to one pixel unit 120, and a single masking element 11 surrounds a single pixel unit 120. Furthermore, a single masking element 11 has a side portion 11L. When the masking tool 10 is placed on the circuit board 110, the side portion 11L of the masking element 11 surrounds a single pixel unit 120. In addition, a single masking element 11 has a top portion 11T. When the masking tool 10 is placed on the circuit board 110, the top portion of the masking element 11 covers a single pixel unit 120.

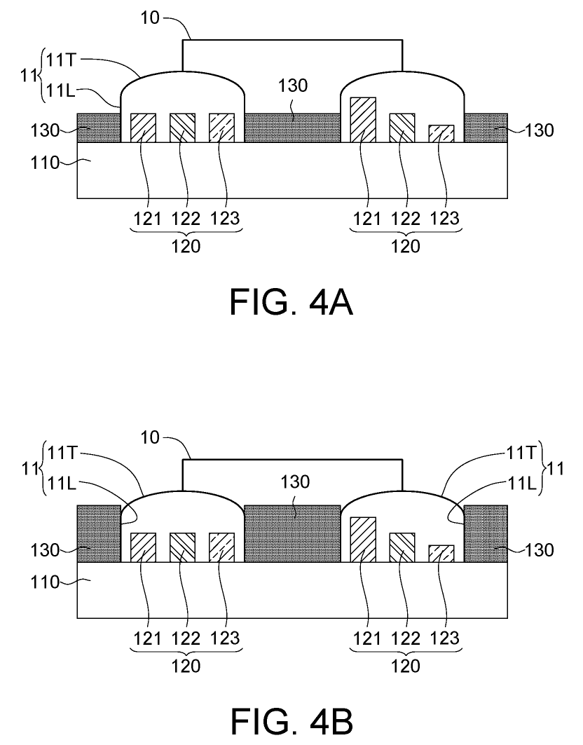

Then, in the step S130, form an opaque layer 130 on the circuit board 110. The opaque layer 130 may be, for example, a curable black ink, which may be sprayed onto the circuit board 110 through a tool such as a nozzle. As shown in FIGS. 4A and 4B, the opaque layer 130 is formed in the areas between the plurality of masking elements 11. Moreover, due to the presence of the masking tool 10, the opaque layer 130 is not in contact with the plurality of pixel units 120. FIGS. 4A and 4B respectively illustrate possible implementations in which the opaque layer 130 is configured at different heights. Specifically, as shown in FIG. 4A, in a side view, the height of the opaque layer 130 is equal to the height of the left sub-pixels 121, 122, and 123, and the height of the opaque layer 130 is less than the height of one of the right sub-pixels, specifically smaller than the height of the right sub-pixel 121. As shown in FIG. 4B, in a side view, the height of the opaque layer 130 is greater than the height of the sub-pixels 121, 122, and 123 on both the left and right sides.

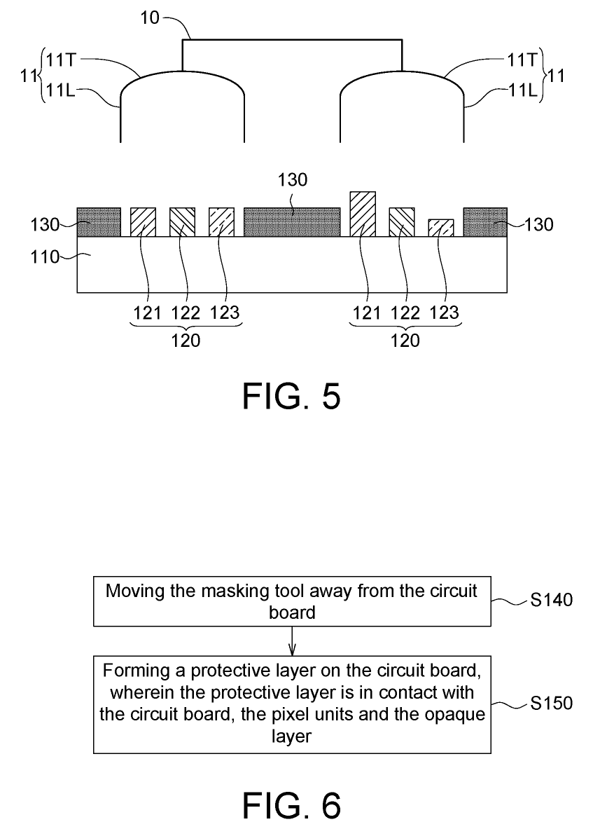

Next, in the step S140, move the masking tool 10 away from the circuit board 110. After the opaque layer 130 is cured, the masking tool 10 can be removed from the circuit board 110. Thus, as shown in FIG. 5, the opaque layer 130 is formed on the circuit board 110 without being in contact with the pixel units 120. In other words, the situation where the opaque layer 130 covers the pixel units 120 no longer occurs, thereby improving process yield and enabling production cost control. In addition, due to the use of the masking tool 10, the opaque layer 130 will not cover the pixel units 120, which eliminates the need for the conventional process step of removing the black ink covering the surface of the pixel units using plasma.

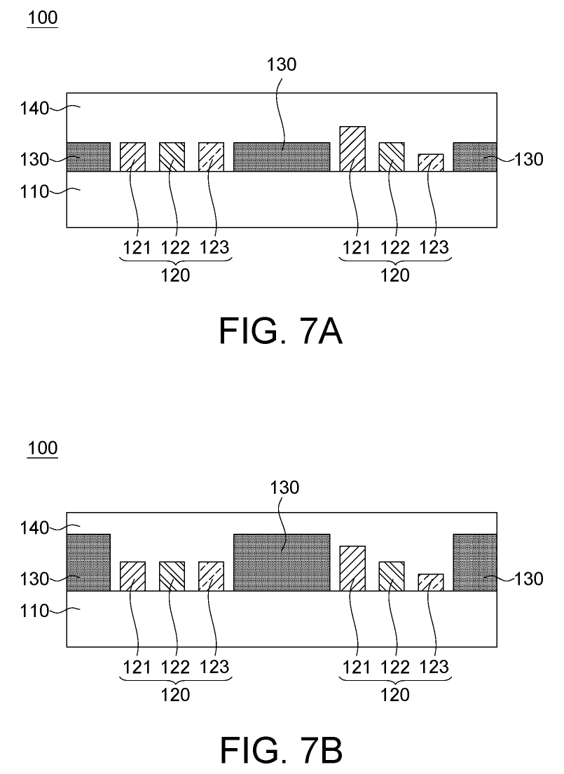

Please refer to FIGS. 6, 7A, and 7B. FIG. 6 illustrates a further flowchart of the method S for manufacturing the display module 100, and FIGS. 7A and 7B illustrate the situations of implementing steps the method S for manufacturing the display module 100 and the display module 100.

The method S for manufacturing the display module 100 according to the embodiment of the present invention may further comprise a step S150. The following description explains the step S150 with reference to the contents shown in FIGS. 7A and 7B.

After the step S140, step S150 may be performed. In step S150, a protective layer 140 is disposed on the circuit board 110. The protective layer 140 may be, for example, a curable transparent gel, which may be applied onto the circuit board 110. FIGS. 7A and 7B illustrate scenarios in which the protective layer 140 is disposed on the circuit board 110 corresponding to the different height configurations of the opaque layer 130 shown in FIGS. 4A and 4B. As shown in FIGS. 7A and 7B, the protective layer 140 contacts the circuit board 110, the plurality of pixel units 120 and the opaque layer 130. In other words, the sub-pixels 121, 122, and 123 and the opaque layer 130 are encapsulated together by the protective layer 140. Since the pixel units 120, which serve as light-emitting units, are completely encapsulated by the protective layer 140 without an air medium between them, no reflection loss occurs during light emission. As shown in FIGS. 7A and 7B, in a side view, the height of the protective layer 140 is greater than the height of the pixel units 120 and the opaque layer 130.

After the protective layer 140 is disposed, the display module 100 of the representative embodiment of the present invention is formed. As shown in FIGS. 7A and 7B, the display module 100 comprises the circuit board 110, the plurality of pixel units 120, the opaque layer 130 and the protective layer 140. The pixel units 120 are disposed on the circuit board 110. The opaque layer 130 is formed on the circuit board 110 without being in contact with the pixel units 120. The protective layer 140 is formed on the circuit board 110 and is in contact with the circuit board 110, the pixel units 120 and the opaque layer 130.

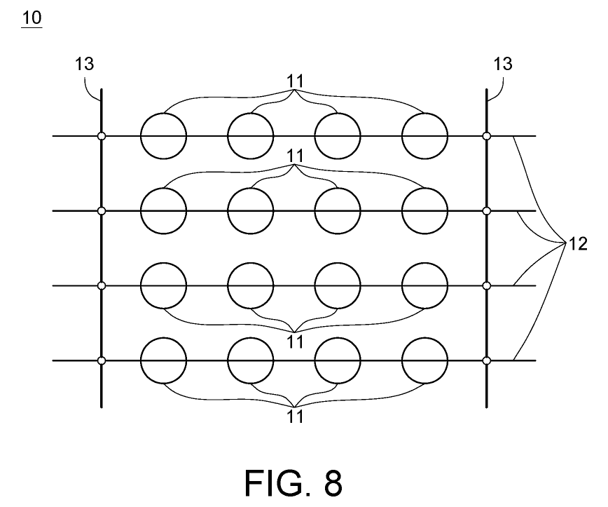

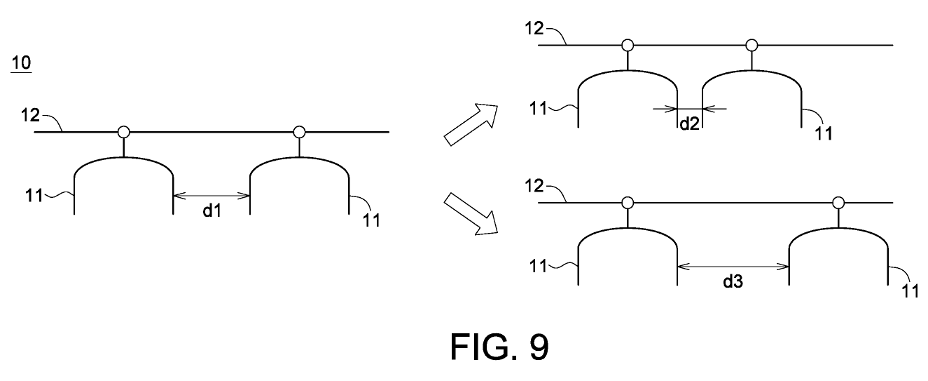

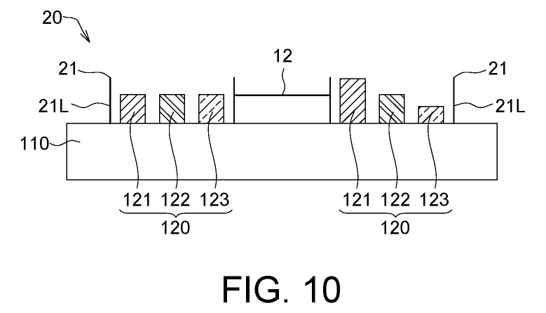

Please refer to FIGS. 8, 9, and 10. FIG. 8 illustrates a top view of the masking tool 10 used in the method S for manufacturing the display module 100. FIG. 9 illustrates a schematic view of the masking tool 10 used in the method S for manufacturing the display module 100. FIG. 10 illustrates a schematic view of another masking tool 20 that can be used in the method S for manufacturing the display module 100.

As shown in FIG. 8, in a top view, the masking tool 10 includes transverse bars 12 and longitudinal bars 13. At least a portion of the plurality of masking elements 11 may be connected by a single transverse bar 12. The numbers of the transverse bars 12 and longitudinal bars 13 may each be plural. In this embodiment, four transverse bars 12 and two longitudinal bars 13 are illustrated as an example. A single transverse bar 12 may be connected with, for example, four masking elements 11. The transverse bars 12 may be arranged at intervals and connected between the two longitudinal bars 13. In other words, the transverse bars 12 are arranged at intervals between the two longitudinal bars 13. Furthermore, the transverse bars 12 are movably connected to the two longitudinal bars 13. That is, the distance between every two transverse bars 12 is adjustable to accommodate different layout types of the pixel units 120 on the circuit board 110. As shown in FIG. 8, in a top view, the shape of the masking element 11 may be circular, but is not limited thereto. The shape of the masking element 11 may also be an ellipse, polygon, or irregular geometric shape depending on practical needs.

At least a portion of the plurality of masking elements 11 may be movably connected to the transverse bars 12. That is, some or all of the masking elements 11 may be movably arranged. As shown in FIG. 9, the distance between every two masking elements 11 along the extending direction of the transverse bar 12 is adjustable. The distance between the masking elements 11 may be adjusted from a distance d₁ to a distance d₂, where distance d₁ is greater than distance d₂, meaning the masking elements 11 are closer to each other. Alternatively, the distance between the masking elements 11 may be adjusted from distance d₁ to distance d₃, where distance d1 is smaller than distance d3, meaning the masking elements 11 are farther apart. Thus, the design can accommodate different layout types of the pixel units 120 on the circuit board 110.

The method S for manufacturing the display module 100 according to an embodiment of the present invention may also use another masking tool 20. The masking tool 20 may include a plurality of masking elements 21. As shown in FIG. 10, the masking elements 21 of the masking tool 20 do not include a top portion 11T as in the masking elements 11, but are instead designed to include only side portions 21L. Two masking elements 21 may be connected through the transverse bar 12. The side portion 21L has an annular shape with an opening. That is, when the masking tool 20 is placed on the circuit board 110, a single pixel unit 120 may be exposed from the opening defined by the side portion 21L. With this design, the material used for forming the masking elements 21 of the masking tool 20 can be saved.

In summary, the display module 100 and the method S for manufacturing the same of the present invention can prevent the opaque layer 130 from covering the pixel units 120, thereby eliminating the conventional process step of removing the black ink covering the surface of the pixel units using plasma, and even eliminating the need for conventional scrapping procedures. Accordingly, the display module 100 and the method S for manufacturing the same of the present invention can solve the problems in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a display module, comprising:
providing a circuit board, wherein a plurality of pixel units are disposed on the circuit board;
placing a masking tool on the circuit board, wherein the masking tool includes a plurality of masking elements, the masking elements respectively correspond to the pixel units, and a single one of the masking elements surrounds a single one of the pixel units;
forming an opaque layer on the circuit board, wherein the opaque layer is formed in areas between the masking elements and is not in contact with the pixel units; and
moving the masking tool away from the circuit board.

2. The method for manufacturing the display module according to claim 1, wherein the masking tool includes a transverse bar, and at least some of the masking elements are connected via the transverse bar.

3. The method for manufacturing the display module according to claim 2, wherein a plurality of the transverse bars are provided, and the transverse bars are arranged at intervals.

4. The method for manufacturing the display module according to claim 2, wherein at least some of the masking elements are movably connected to the transverse bar.

5. The method for manufacturing the display module according to claim 2, wherein the masking tool includes two longitudinal bars, and the transverse bar is connected between the two longitudinal bars.

6. The method for manufacturing the display module according to claim 5, wherein a plurality of the transverse bars are provided, and the transverse bars are arranged at intervals between the two longitudinal bars.

7. The method for manufacturing the display module according to claim 5, wherein the transverse bar is movably connected to the two longitudinal bars.

8. The method for manufacturing the display module according to claim 1, wherein a plurality of the transverse bars are provided, and the transverse bars are arranged at intervals between two longitudinal bars.

9. The method for manufacturing the display module according to claim 1, wherein a single one of the masking elements has a side portion, and when the masking tool is placed on the circuit board, the side portion surrounds a single one of the pixel units.

10. The method for manufacturing the display module according to claim 8, wherein a single one of the masking elements has a top portion, and when the masking tool is placed on the circuit board, the top portion covers a single one of the pixel units.

11. The method for manufacturing the display module according to claim 9, wherein the side portion is annular in shape and has an opening, and when the masking tool is placed on the circuit board, a single one of the pixel units is exposed from the opening.

12. The method for manufacturing the display module according to claim 1, further comprising:
forming a protective layer on the circuit board, wherein the protective layer is in contact with the circuit board, the pixel units and the opaque layer.

13. A display module, comprising:
a circuit board;
a plurality of pixel units disposed on the circuit board;
an opaque layer formed on the circuit board and being not in contact with the pixel units; and
a protective layer formed on the circuit board and being in contact with the circuit board, the pixel units and the opaque layer.

14. The display module according to claim 13, wherein a single one of the pixel units includes a plurality of sub-pixels.

15. The display module according to claim 14, wherein in a side view, the sub-pixels have different heights from each other.

16. The display module according to claim 14, wherein in a side view, the sub-pixels have the same height.

17. The display module according to claim 14, wherein in a side view, a height of the opaque layer is less than a height of one of the sub-pixels.

18. The display module according to claim 14, wherein in a side view, a height of the opaque layer is greater than heights of the sub-pixels.

19. The display module according to claim 14, wherein in a side view, a height of the opaque layer is equal to heights of the sub-pixels.

20. The display module according to claim 13, wherein in a side view, a height of the protective layer is greater than heights of the pixel units and the opaque layer.
